(19) United States
(12) Patent Application Publication
(10) Pub. No.: US 2024/0347530 A1
(43) Pub. Date: Oct. 17, 2024

(54) ELECTRO-STATIC DISCHARGE PROTECTION CIRCUIT

(71) Applicant: LX SEMICON CO., LTD., Daejeon (KR)

(72) Inventors: Min Cheol KONG, Daejeon (KR); Jin Gyoung JUNG, Daejeon (KR); Keun Hwa JUNG, Daejeon (KR)

(73) Assignee: LX SEMICON CO., LTD., Daejeon (KR)

(21) Appl. No.: 18/750,727

(22) Filed: Jun. 21, 2024

Related U.S. Application Data
(63) Continuation of application No. PCT/KR2022/021164, filed on Dec. 23, 2022.

(30) Foreign Application Priority Data
Dec. 23, 2021 (KR) 10-2021-0186388

(51) Int. Cl. H01L 27/02

(52) U.S. Cl. CPC H01L 27/0277

(57) ABSTRACT

The present invention provides an electro-static discharge protection circuit including an input pad terminal; a ground pad terminal; a first Metal Oxide Semiconductor (MOS) transistor, wherein a source or drain terminal of the first MOS transistor is electrically connected to the input pad terminal and a gate of the first MOS transistor is electrically connected to the ground pad terminal; a second MOS transistor, wherein a source or drain terminal of the second MOS transistor is electrically connected to the ground pad terminal and a gate of the second MOS transistor is electrically connected to the input pad terminal; a common node in which the remaining terminal not connected to the input terminal among the source or drain of the first MOS transistor and the remaining terminal not connected to the ground terminal among the source or drain of the second MOS transistor are electrically connected to each other.

### CROSS REFERENCE TO RELATED APPLICATION(S)

This application is a Bypass Continuation application of PCT/KR2022/021164, filed on Dec. 23, 2022, which claims the benefit of Korean Patent Application No. 10-2021-0186388, filed on Dec. 23, 2021, the disclosures of which are herein incorporated by reference in their entirety.

### TECHNICAL FIELD

The present invention relates to an electro-static discharge protection circuit for a semiconductor chip, and more specifically, to a circuit structure for more effectively controlling overcurrent conditions such as latch-up in an integrated circuit with a Bipolar CMOS Double diffused (BCD) device structure.

### BACKGROUND

With the development of semiconductor technology, increasingly complex and diverse types of Integrated Circuit (IC) chips are being produced. Among these, more diverse technologies have been developed so that various elements can be formed on a single substrate. In particular, the Bipolar CMOS Double-diffused (BCD) process, which can form bipolar transistors, CMOS transistors, and double diffused MOS transistors for high-power all on a single substrate, is also being actively used. In the BCD process, different types of transistor elements can be mixed and formed on a single substrate, which has the great advantage of taking up a much smaller area than in case each type of transistor existed on a separate substrate. On the other hand, to form various types of transistors, more complex process steps are required, thereby having a disadvantage of increasing the manufacturing cost.

Meanwhile, to prevent electro-static destruction caused by static electricity, the semiconductor chip has an Electro-Static Discharge protection (ESD) element connected to the input/output pad for electrical communication with an external. Static electricity is a common occurrence in daily life and tends to become particularly severe during the winter. Even if a semiconductor chip is held by hand or a machine and then static electricity enters an interior of the integrated circuit through the pins of the semiconductor package, it usually causes physical damage such as destruction of the oxide film of the transistor and destruction of the PN junction. Accordingly, an ESD element is essentially necessary. This is no exception even when using the BCD process, so more reliable ESD elements are needed.

### DETAILED DESCRIPTION

### Technical Problem

The technical problem to be solved by the present invention is to provide an electro-static discharge protection circuit for protecting an internal circuit of a semiconductor chip from static electricity.

Another aspect of the technical problem to be solved by the present invention is to provide an electro-static discharge protecting function of a parasitic bipolar circuit for proper operation of the electro-static discharge protection circuit in a semiconductor chip based on a CMOS circuit.

Another aspect of the technical problem to be solved by the present invention is to eliminate the instability in which several nodes of inside of the circuit are in a floating state during the electro-static discharge protecting operation to ensure proper operation of the electro-static discharge protection circuit in the semiconductor chip based on the CMOS circuit, thereby providing a correct electro-static discharge protection function.

### Technical Solution

According to one embodiment of the present invention for solving the above problem, it may include an input pad terminal; a ground pad terminal; a first Metal Oxide Semiconductor (MOS) transistor, wherein a source or drain terminal of the first MOS transistor is electrically connected to the input pad terminal and a gate of the first MOS transistor is electrically connected to the ground pad terminal; a second MOS transistor, wherein a source or drain terminal of the second MOS transistor is electrically connected to the ground pad terminal and a gate of the second MOS transistor is electrically connected to the input pad terminal; and a common node in which the remaining terminal not connected to the input terminal among the source or drain of the first MOS transistor and the remaining terminal not connected to the ground terminal among the source or drain of the second MOS transistor are electrically connected to each other.

According to one embodiment of the present invention for solving the above problem, it may include an input pad terminal; a ground pad terminal; a first MOS transistor whose source or drain terminal is electrically first and second MOS transistors connected in series to the input pad terminal and the ground pad terminal; a first parasitic bipolar transistor formed by the source, drain, and body of the first MOS transistor; a second parasitic bipolar transistor formed by the source, drain, and body of the second MOS transistor; and a third parasitic bipolar transistor formed by the body of the first MOS transistor, the body of the second MOS transistor, and a well that isolates either the first MOS transistor or the second MOS transistor alone.

According to one embodiment of the present invention for solving the above problem, it may include an input pad terminal; a ground pad terminal; a first MOS transistor connected to the input pad terminal; a second MOS transistor connected to the ground pad terminal; a first parasitic bipolar transistor formed by the source, drain, and body of the first MOS transistor; an electro-static discharge protection operation is performed by a turn-on operation of at least one of the first MOS transistor or the first parasitic bipolar transistor corresponding to the static electricity interfering with the input pad terminal.

According to one embodiment of the present invention for solving the above problem, it may include an input pad terminal; a ground pad terminal; a first MOS transistor connected to the input pad terminal; a second MOS transistor connected to the ground pad terminal; a second parasitic bipolar transistor formed by the source, drain, and body of the second MOS transistor; an electro-static discharge protection operation is performed by a turn-on operation of at least one of the second MOS transistor or the second parasitic bipolar transistor corresponding to the static electricity interfering with the input pad terminal.

### Effect of the Invention

According to the present invention, an internal circuit of a semiconductor chip is safely protected by an operation of the electro-static discharge protection circuit when positive or negative static electricity enters.

In addition, the electro-static discharge protection circuit also has an electrical potential set without floating any internal nodes during the electro-static discharge protection operation, so a stable electro-static discharge protection can be performed.

### BRIEF DESCRIPTION OF THE DRAWINGS

FIG. 1 is a simplified circuit diagram of the present invention.

FIG. 2 illustrates a cross-section of the structure of the present invention.

FIG. 3 is a diagram illustrating the addition of parasitic bipolar transistors when positive static electricity is entered in the present invention.

FIG. 4 is an equivalent circuit diagram redrawn with the parasitic bipolar transistors in the drawing of FIG. 3 as the center.

FIG. 5 is a diagram illustrating the addition of parasitic bipolar transistors when negative static electricity is entered in the present invention.

FIG. 6 is an equivalent circuit diagram redrawn with the parasitic bipolar transistors in the drawing of FIG. 5 as the center.

FIG. 7 is a diagram re-illustrated focusing on the MOS transistors when positive static electricity is entered in the present invention.

FIG. 8 is a diagram re-illustrated focusing on the MOS transistors when negative static electricity is entered in the present invention.

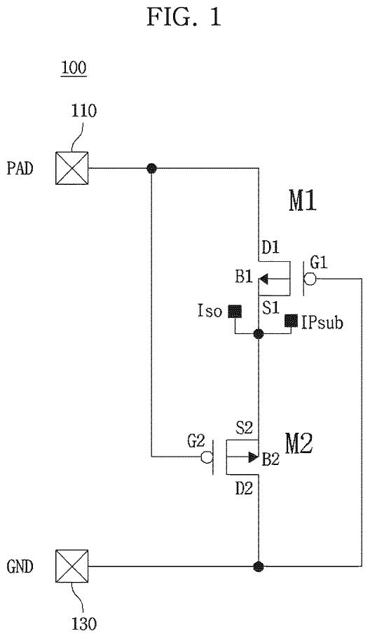

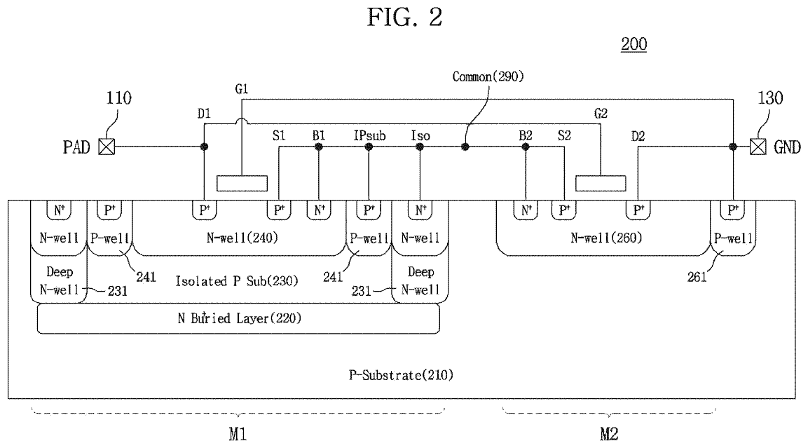

Hereinafter, an embodiment of the present invention will be described with reference to FIGS. 1 and 2, which illustrate structural aspects of the present invention. FIG. 1 illustrates an equivalent circuit 100 of the present invention, focusing mainly on a MOS transistor, and FIG. 2 illustrates a cross-section of a semiconductor substrate after the necessary elements are formed. In these figures, each terminal D1, G1, S1, and B1 represents a drain, a gate, a source, and a body of transistor M1, and each terminal D2, G2, S2, and B2 represents a drain, a gate, a source, and a body of transistor M2. An input pad (PAD, reference numeral 110) is simultaneously connected to the drain (D1) terminal of transistor M1 and the gate (G2) terminal of transistor M2, and a ground pad (GND, reference numeral 130) is connected to the drain (D2) terminal of transistor M2 terminal and the gate (G1) terminal of transistor M1 at the same time. The source (S1, S2) terminals of the two transistors (M1, M2) are connected to each other, and the terminals specifically marked as Iso and Isub are also connected together.

FIG. 2 is a cross-sectional view 200 illustrating one embodiment of the present invention. A cross section of two transistors M1 and M2 is shown on a P-type semiconductor substrate 210. Among them, the transistor M1 is sequentially formed an N+Buried Layer 220 which is an N-type buried layer, an Isolated Psub 230 which is a P-type separated substrate layer, and an N-well 240 which is a body, on the semiconductor substrate 210. Inside the N-well 240 body, the drain (D1) and source (S1) are formed as P+ types, forming the transistor M1 together with the gate (G1). The N-well 240 body is surrounded and protected by the P-well 241 and the Isolated Psub 230. The Isolated Psub 230 is protected by being surrounded and isolated by a double layer of the Deep N-well 231 and the N-well (not shown) above the Deep N-well 231. In the manufacturing process, when the N-well 240 body is formed, the N-well (not shown) on the top of the Deep N-well 231 is also formed at the same time. The Deep N-well 231, its upper N-well (not shown), and N+Buried Layer 220 are doped with the same N-type impurity. That is, the transistor M1 is isolated and protected by being surrounded as a double of layers having N-type impurities in the outermost, such as N+Buried Layer 220, Deep N-well 231, and N-well (not shown) and having P-type impurities, such as P-well 241 and Isolated Psub 230, and due to this structure, the transistor M1 is isolated and distinguished from other elements.

The drain (D2) and the source (S2) formed inside the N-well body 260 formed on the P-type substrate 210 are formed in the transistor M2, and the P-type substrate 210 maintains the same electrical potential by the P-well 261.

Next, electrical connection state of the common node 290 of the structure of the present invention will be described with reference to the cross section shown in FIG. 2. First, the N-well 240 of transistor M1 is biased through the body (B1) node, and the Isolated Psub 230, which is an isolated substrate, is biased simultaneously with the P-well 241 by the IPsub node, and the N+Buried Layer 220, Deep N-well 231, and N-well (not shown) are biased through the Iso node, respectively. More importantly, the source (S1), body (B1), and nodes IPsub and Iso of the isolated substrate are all tied to one node, the common (reference numeral 290). The source (S2) and body (B2) of the transistor M2 are also connected to the common node 290. Therefore, there is no electrical potential difference between the N-well 240, the Isolated Psub 230, and the N+ Buried Layer 220 of the transistor M1, so forward voltage is not applied to the PN junction formed by them, thereby preventing unnecessary turn-on operation. The source (S2) and the body (B2) of the transistor M2 are both connected to the common node 290, and the P-type substrate 210 is biased at a fixed electrical potential through the P-well 261.

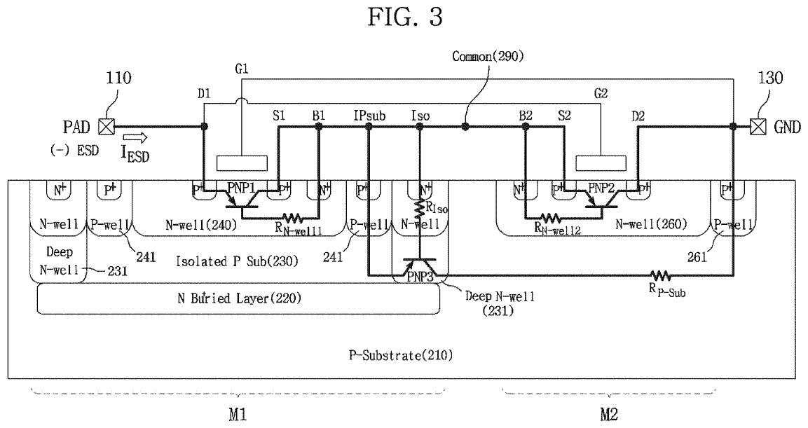

FIG. 3 is a cross-sectional view of FIG. 2 with a parasitic bipolar transistor added thereto. With reference to this, the electro-static discharge protecting operation will be explained. In particular, FIG. 3 assumes that positive static electricity is entered. First, there are three parasitic bipolar transistors, denoted as PNP1, PNP2, and PNP3, respectively. In PNP1, the N-well body 240, the source (S1), and the drain (D1) of the M1 become a base, a collector, and an emitter, respectively, to form a lateral PNP bipolar transistor (PNP1). In the second parasitic bipolar transistor (PNP2), the N-well body 260, the drain (D2), and the source (S2) of the M2 become a base, a collector, and an emitter, respectively, to form another lateral PNP bipolar transistor. The third parasitic bipolar transistor (PNP2) is the Deep N-well 231, the N-well (not shown) on its top, a P-type substrate (P-Substrate, 210), the Isolated Psub 230, and the P-Well 241 becomes a base, a collector, and an emitter, respectively. Resistors R_{N-Well1}, R_{Iso}, and R_{N-Well2} connected to the three parasitic bipolar transistors represent an N-Well body 240 resistor, a Deep N-Well 231 resistor, and an N-Well body 260 resistor, respectively.

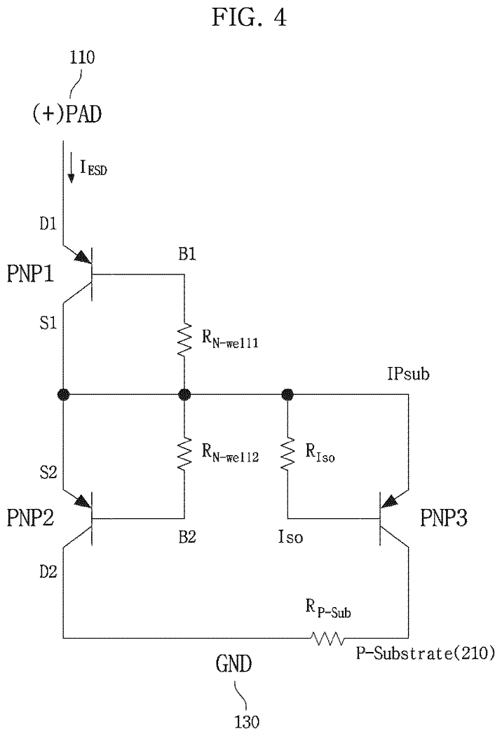

These connection states can be expressed as an equivalent circuit as shown in FIG. 4. The first parasitic bipolar transistor (PNP1) and the second parasitic bipolar transistor (PNP2) are connected in series between the input pad 110 and the ground (GND) pad 130. The second parasitic bipolar transistor (PNP2) and the third parasitic bipolar transistor (PNP3) share the emitter terminal as the common node 290, and collector terminals of them are connected to the ground (GND) pad 130. The advantage of this circuit structure is that a latch-up structure that causes the current avalanche phenomenon can be avoided.

For reference, the latch-up structure in the MOS transistor process is caused by the base-collectors of the NPN and PNP parasitic bipolar transistors being tied to each other. Here, when a trigger voltage or higher is involved, a feed forward of the current between the two parasitic transistors occurs, causing an instantaneous current runaway phenomenon, which ultimately destroys the element due to the resulting ohmic heat. Since this phenomenon is irreversible, the destroyed element cannot be recovered even if the current is cut off later and becomes permanently disabled. As can be seen from FIG. 4, in the present invention, the parasitic bipolar transistors are breaking away from the structure that causes latch-up.

Hereinafter, the electro-static discharge protecting operation of the present invention when a positive electro-static discharge voltage is applied to the input pad 110 will be described. To understand this, FIGS. 1, 3, 4, and 7 should be referred to together and kept in mind. When a positive electro-static voltage ranging from hundreds to thousands of volts enters the input pad 110, the drain (D1) voltage of M1, a P-channel MOS transistor, becomes higher than the gate (G1) voltage, so M1 can be turned on. Therefore, all of the source (S1) and the body (B1) of M1, which is the common node 290, the terminal IPsub of the Isolated Psub 230, the terminal Iso of the double layer of Deep N-Well 231 and N-Well, etc. are equivalent to the voltage of input pads 110. At this time, a positive electro-static voltage is also applied to the gate (G2) of the P-channel MOS transistor M2, so M2 maintains in the off state.

Meanwhile, since the base of the second parasitic bipolar transistor PNP2 is connected to the common node 290, this voltage is also applied as a positive (+) electro-static voltage. However, since the collector of PNP2 is connected to the ground pad 130, an electrical potential difference as equal to the positive electro-static voltage difference occurs in between the collector and the base of PNP2. This electrical potential difference causes avalanche breakdown due to high reverse voltage to the PN junction diode between the collector and the base of PNP2. A voltage is formed on the base resistor (R_{N-Well2}) of the PNP2 by the avalanche breakdown current, and the PNP2 is turned on, so that the current due to the positive electro-static voltage is easily discharged to the ground pad 130.

Additionally, a breakdown voltage between the collector and the base of the third parasitic bipolar transistor PNP3 is higher than that of the other parasitic bipolar transistors due to the difference in doping concentration, and the current amplification rate is relatively low. Because of this, when positive static electricity is entered, the transistor PNP3 is not activated and may not contribute to the discharge of positive electro-static voltage.

Additionally, when the collector and the base of the third parasitic bipolar transistor PNP3 have an appropriate doping concentration, the positive electro-static voltage along with the PNP2 can be simultaneously discharged to the ground.

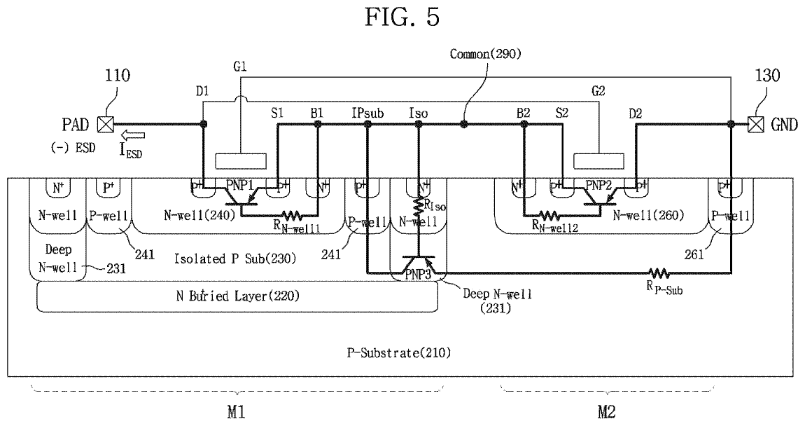

FIG. 5 illustrates a cross-sectional view of FIG. 2 with a parasitic bipolar transistor. Unlike FIG. 3, FIG. 5 assumes that negative static electricity is entered. First, there are three parasitic bipolar transistors in the same position, and they are denoted as PNP1, PNP2, and PNP3, respectively. However, the positions of the source and the collector are switched. In PNP1, the N-well body 240 of the M1, the source (S1), and the drain (D1) become a base, an emitter, and a collector, respectively, to form a lateral PNP bipolar transistor (PNP1). In the second parasitic bipolar transistor (PNP2), the N-well body 260, the drain (D2), and the source (S2) of the M2 become a base, an emitter, and a collector, respectively, forming another lateral PNP bipolar transistor. In the third parasitic bipolar transistor (PNP3), a Deep N-well 231 and an N-well (not shown) on its upper part, a P-type substrate (P-Substrate, 210), and an Isolated Psub 230 and a P-Well 241 becomes a base, an emitter, and a collector, respectively. Resistors R_{N-Well1}, R_{Iso}, and R_{N-Well2} connected to the three parasitic bipolar transistors represent the N-Well body 240 resistor, Deep N-Well 231 resistor, and N-Well body 260 resistor, respectively.

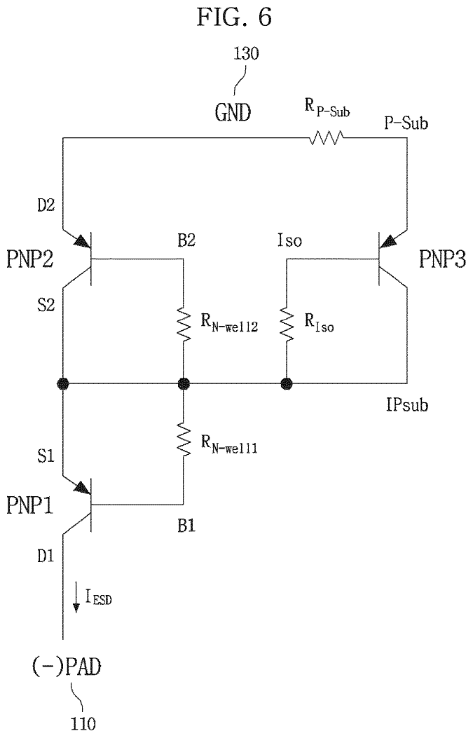

These connection states can be expressed as an equivalent circuit as shown in FIG. 6. Note that the input pad 110 is assumed to be when a negative (−) electro-static voltage is input, so the ground (GND) pad 130 with a high electrical potential is indicated upward, and the input pad 110 with a low electrical potential is indicated downward. The first parasitic bipolar transistor (PNP1) and a second parasitic bipolar transistor (PNP2) are connected in series between the input pad 110 and the ground (GND) pad 130. The second parasitic bipolar transistor (PNP2) and the third parasitic bipolar transistor (PNP3) share a collector terminal as a common node 290, and emitter terminals are connected to a ground (GND) pad 130. The advantage of this circuit structure is that the latch-up structure that causes the current avalanche phenomenon can be avoided.

For reference, as described above, the latch-up structure in the MOS transistor process is caused by the base-collectors of the NPN and PNP parasitic bipolar transistors being tied to each other. Here, when a trigger voltage or higher is entered, a feed forward of current between the two parasitic transistors occurs, causing an instantaneous current runaway phenomenon, which ultimately destroys the device due to ohmic heat. This phenomenon is irreversible, so the destroyed element cannot be restored even if the current is cut off later, making it permanently disabled. As can be seen from FIG. 6, in the present invention, parasitic bipolar transistors are breaking away from the structure that causes latch-up.

Next, the electro-static discharge preventing operation of the present invention when a negative electro-static voltage is applied to the input pad 110 will be described. To understand this, FIGS. 1, 5, 6, and 8 should be referred to together and kept in mind. When a negative electro-static voltage of several hundred to several thousand volts enters the input pad 110, the gate (G2) voltage of the M2, which is a P-channel MOS transistor, becomes lower than the source (S2) voltage, so the M2 turns on. Therefore, all of the source (S2) and the body (B2) of M2, which is the common node 290, the terminal IPsub of the Isolated Psub 230, the terminal Iso of the double layer of the Deep N-Well 231 and the N-Well, etc. are electrically connected to ground pad (GND, 130) and becomes equal to the ground voltage. At this time, a negative electro-static voltage is also applied to the drain (G1) of the P-channel MOS transistor M1, so M1 maintains the off state.

Meanwhile, the base of the first parasitic bipolar transistor PNP1 is connected to the common node 290 so that its voltage becomes equal to the voltage of the ground pad (GND, 130). However, since the collector of PNP1 is connected to the input pad 110 an electrical potential difference as the negative electro-static voltage difference occurs in between the collector and base of PNP1. This electrical potential difference causes avalanche breakdown due to high reverse voltage to the PN junction diode between the collector-base of PNP1. A voltage is formed on the base resistor (R_{N-Well1}) of PNP1 by the avalanche breakdown current, and PNP1 is turned on, so that the current due to the negative (−) electro-static voltage is also easily discharged.

The operational mechanism for appropriately discharging such a negative (−) electro-static voltage can be a symmetrical to the operation for discharging the positive (+) electro-static voltage.

In addition, electro-static discharge protecting operation is performed through an appropriate combination of MOS transistor and parasitic bipolar transistors. For example, a turn-on operation of one or more MOS transistors and a operation by the reverse breakdown voltage appearing at the PN junction of one or more parasitic bipolar transistors may be combined to discharge the electro-static voltage. One embodiment of the present invention is a combination of M1-PNP2 and M2-PNP1, but there may be various other combinations. Additionally, similar examples can be easily generated not only when the MOS transistor is P-channel but also when it is N-channel. A similar example can be made with the parasitic bipolar transistor by introducing not only the PNP type but also the NPN type.

Therefore, the electro-static discharge protecting effect of the present invention is readily apparent regardless of whether positive (+) or negative (−) static electricity is introduced. In particular, there is an advantage that the electrical potential is always set without floating the node such as the common node 290 or the Iso node representing a node of the N-Well forming a double layer with the Deep N-Well 231. Thus, the turn-on of parasitic transistors, which are essential for electro-static discharge preventing operation, and the flow of electro-static current can be made flexible. As a result, accurate electro-static discharge preventing operation of the parasitic transistors can be achieved, and the advantages of the present invention are more clearly revealed.

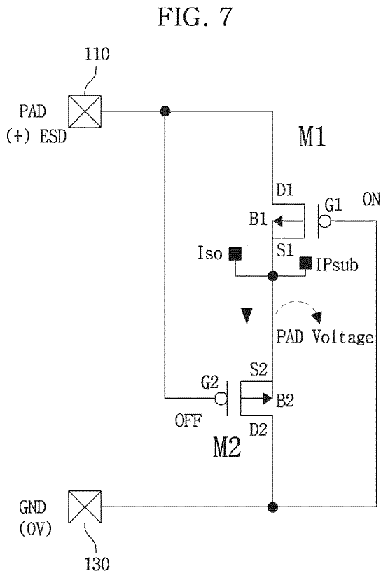

Hereinafter, an operation of the circuit of MOS transistors M1 and M2 when positive (+) and negative (−) static electricity is applied will be described. FIG. 7 illustrates a case where positive static electricity enters the input pad 110. First, PMOS transistor M1 is turned on because the voltage at the drain (D1) becomes higher than the threshold voltage than the voltage of the gate (G1) due to positive static electricity, and static current flows in between the drain (D1) and the source (S1). Since the input pad 110 is simultaneously connected to the gate (G2) of the PMOS transistor M2, the voltage of the gate (G2) is higher than the voltage of the drain (D2), so M2 maintains in the off state. The current passing through a channel of transistor M1 is discharged to the ground (GND) pad 130 through a path by the above-described parasitic bipolar transistors rather than transistor M2. Hereinafter, throughout the specification of the present invention, PMOS is referred to as a P-channel MOS transistor with a P-type channel.

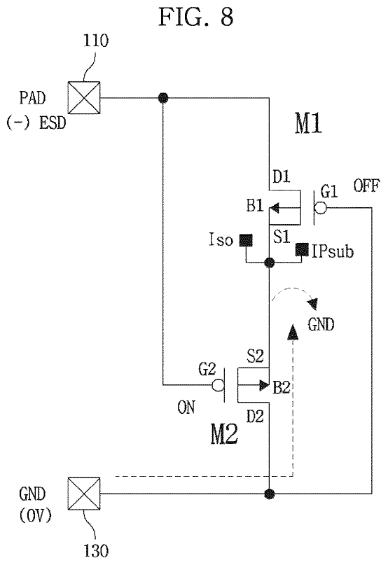

A similar explanation applies when negative static electricity is introduced. This will be explained with reference to FIG. 8. The gate (G2) of transistor M2 and the drain (D1) of transistor M1 are both connected to the input pad 110. Therefore, when negative static electricity enters, the gate (G2) voltage of transistor M2 becomes lower than the source (G2) voltage, and when such a voltage difference exceeds the threshold voltage of transistor M2, M2 turns on. However, transistor M1 maintains in the off state. When transistor M2 is turned on, the current passing through the channel of M2 is discharged to the ground pad (GND, 130) through the above-described parasitic bipolar transistors rather than transistor M1. As a result, the discharge path of static electricity is completed regardless of whether positive (+) or negative (−) static electricity enters, so that the interior circuit of the semiconductor chip is free from the influence of static electricity and can be protected from static electricity.

Although the preferred embodiments of the present invention have been described in detail above, the scope of the present invention is not limited thereto, and can be implemented in more various embodiments based on the basic concept of the present invention defined in the following claims. The embodiments also fall within the scope of the present invention.

What is claimed is:

1. An electro-static discharge protection (ESD) circuit, comprising:
an input pad terminal;
a ground pad terminal;
a first Metal Oxide Semiconductor (MOS) transistor, wherein a source or drain terminal of the first MOS transistor is electrically connected to the input pad terminal and a gate of the first MOS transistor is electrically connected to the ground pad terminal;
a second MOS transistor, wherein a source or drain terminal of the second MOS transistor is electrically connected to the ground pad terminal and a gate of the second MOS transistor is electrically connected to the input pad terminal; and
a common node in which the remaining terminal not connected to the input terminal among the source or drain of the first MOS transistor and the remaining terminal not connected to the ground terminal among the source or drain of the second MOS transistor are electrically connected to each other.

2. The ESD circuit according to claim 1, wherein the first and second MOS transistors are P-channel MOS transistors.

3. The ESD circuit according to claim 1, wherein the common node does not electrically float while the ESD is operated.

4. The ESD circuit according to claim 1, wherein one of the first and second MOS transistors is located at a buried layer of an impurity type different from the channel impurity type of the first MOS transistor is located under the channel to isolate it from the semiconductor substrate.

5. The ESD circuit according to claim 4, wherein an isolation substrate layer of an impurity type different from that of the buried layer is located between the channel and the buried layer.

6. The ESD circuit according to claim 5, wherein one of the first and second MOS transistors is electrically isolated from the semiconductor substrate by having a well of the same impurity type as the buried layer surrounding the sidewall of the first MOS transistor.

7. The ESD circuit according to claim 5, wherein one of the first and second MOS transistors is characterized in that the buried layer, an isolation substrate of a different type of impurity from the buried layer, and a well of the same type of impurity as the buried layer are formed at different depths under the channel.

8. The ESD circuit according to claim 7, wherein a node for applying voltage to the isolation substrate and a node for applying voltage to the well are connected to the common node.

9. The ESD circuit according to claim 8, wherein the source of one of the first and second MOS transistors is connected to the common node.

10. The ESD circuit according to claim 6, wherein the well is composed of a double layer with different impurity concentrations.

11. The ESD circuit according to claim 6, wherein the well is connected to the common node.

12. The ESD circuit according to claim 1, wherein the source of one of the first and second MOS transistors and a well body are connected to the common node.

13. The ESD circuit according to claim 1, wherein a first parasitic bipolar transistor is formed by the first MOS transistor, and a second parasitic bipolar transistor is formed by the second MOS transistor.

14. The ESD circuit according to claim 6, wherein a third parasitic bipolar transistor is formed by the well, the isolation substrate, and the semiconductor substrate.

15. The ESD circuit according to claim 8, wherein the common node is not floating and has an electric potential set while the ESD is operated.

16. An electro-static discharge protection (ESD) circuit, comprising:
an input pad terminal;
a ground pad terminal;
a first MOS transistor whose source or drain terminal is electrically first and second MOS transistors connected in series to the input pad terminal and the ground pad terminal;
a first parasitic bipolar transistor formed by the source, drain, and body of the first MOS transistor;
a second parasitic bipolar transistor formed by the source, drain, and body of the second MOS transistor; and
a third parasitic bipolar transistor formed by the body of the first MOS transistor, the body of the second MOS transistor, and a well that isolates either the first MOS transistor or the second MOS transistor alone.

17. The ESD circuit according to claim 16, wherein the isolation is in the form of surrounding the corresponding MOS transistor.

18. The ESD circuit according to claim 16, wherein the third parasitic bipolar transistor is connected in parallel with the first or second parasitic bipolar transistor.

19. The ESD circuit according to claim 16, wherein the emitter or collector of the third parasitic bipolar transistor is connected to a common node.

20. An electro-static discharge protection (ESD) circuit, comprising:
an input pad terminal;
a ground pad terminal;
a first MOS transistor connected to the input pad terminal;
a second MOS transistor connected to the ground pad terminal;
a first parasitic bipolar transistor formed by the source, drain, and body of the first MOS transistor; and
a second parasitic bipolar transistor formed by the source, drain, and body of the second MOS transistor,
wherein an ESD operation is performed by a turn-on operation of at least one of the MOS transistor or the parasitic bipolar transistor corresponding to the static electricity interfering with the input pad terminal.
